(19) United States
(12) Patent Application Publication
(10) Pub. No.: US 2012/0267749 A1
(43) Pub. Date: Oct. 25, 2012

(54) SEMICONDUCTOR DEVICE HAVING FUSE ELEMENTS AND GUARD RING SURROUNDING THE FUSE ELEMENTS

(75) Inventors: Shuichi Nagase, Tokyo (JP); Hisayuki Nagamine, Tokyo (JP)

(73) Assignee: Elpida Memory, Inc., Tokyo (JP)

(21) Appl. No.: 13/422,662

(22) Filed: Mar. 16, 2012

(30) Foreign Application Priority Data
Apr. 21, 2011 (JP) 2011-095027

(51) Int. Cl. H01L 29/06

(52) U.S. Cl. 257/488; 257/E29.013

(57) ABSTRACT

The semiconductor memory device has a fuse area in which fuse elements for registering addresses of defective memory cells are arranged. A guard ring is formed around the fuse area and is covered by a passivation film. The passivation film above the fuse area has an opening. The guard ring has a first ring in a first layer, a second ring in a second layer and a third ring in a third layer. These rings are connected by a first connecting ring and a second connecting ring. The first ring is positioned at an inward part of the second ring to provide an area unoccupied by the first ring beneath the second ring.

### BACKGROUND OF THE INVENTION

1. Field of the Invention

The present invention relates to a semiconductor device. More particularly, the invention relates to a semiconductor memory device provided with a function of controlling access to a relief address.

2. Description of Related Art

As a result of an increase in memory capacity of semiconductor memory devices such as dynamic random access memories (DRAMs), the number of memory cells that do not work properly (hereinafter referred to as “defective cells”) tends to increase. Under such circumstances, a semiconductor memory device with spare memory cells known as “redundant cells” is provided in advance. Accesses to the defective cells are replaced by accesses to the redundant cells in order to repair memory addressees of cells. An address of each defective cell to be repaired is hereinafter referred to as the “relief address”. Detection of a defective cell and replacement thereof by a redundant cell are carried out on a semiconductor wafer during the manufacture of a semiconductor memory device. Specifically, an operational test of the wafer is conducted in a manufacturing stage to identify defective cells and information on relief addresses of the defective cells is registered in the semiconductor memory device. In the event that access to any of the relief addresses of the semiconductor memory device is attempted, the access is redirected to a redundant cell to which the relevant relief address is assigned.

It is often the case to use fuse elements which are nonvolatile memory elements as means for storing the relief addresses. The fuse element is initially in an electrically conductive state and can change into a nonconductive state (insulated state) when a current path of the fuse element is interrupted by irradiation with a laser beam. It is possible to represent 1-bit information by the conductive/nonconductive state of the fuse element. Therefore, when selectively irradiated by the laser beam, a plurality of fuse elements can register information on a desired relief address in a nonvolatile fashion. A storing process of the relief addresses is generally referred to as “laser trimming” or “programming.”

A primary surface of a semiconductor chip is coated with a protective film known as the “passivation film” upon completion of a wiring process. After coating, the operational test is carried out to detect defective cells thereof and these defective cells are trimmed. To facilitate trimming, an opening is made in advance in the passivation film which is located immediately above the fuse elements. The laser beam irradiates the fuse elements through this opening. A relief circuit which is provided adjacent to fuse elements identifies relief addresses from the state (bit) of each fuse element and delivers a relief address signal to a memory bank.

The fuse elements are arranged in a specific memory area (hereinafter referred to as a “fuse area”). The fuse area is surrounded by a wall which is referred to as a guard ring and electronic circuits, such as the relief circuit, and various kinds of signal lines are located outside the guard ring.

The guard ring serves as a protective wall for protecting the electronic circuits or the like from stress caused by laser beam irradiation and for avoiding water from entering into an electronic circuit area through the opening in the passivation film (see Japanese Patent Application Laid-Open No. H05-63091).

In a case where a large number of defective cells are formed as in an initial stage of mass production, it is necessary to prepare a large number of fuse elements in advance. An increase in the number of the fuse elements tends to result in an increase in the number of signal lines for transmitting the relief address signal and greater complexity thereof. It should be noted that the increase in the number of the signal lines is likely to cause an increase in circuit scale of a DRAM. Also, since the increased complexity of the signal lines increases transmission time of the relief address signal, it may potentially cause reduction in an access speed.

### SUMMARY

In one embodiment, there is provided a semiconductor memory device that includes: a fuse area in which a plurality of fuse elements are arranged; and a guard ring surrounding the fuse area, the guard ring including a first ring element formed in a first wiring layer and a second ring element formed in a second wiring layer located above the first wiring layer. The first ring element has an outer periphery that is positioned at closer to the fuse area than an outer periphery of the second ring element.

In another embodiment, there is provided a semiconductor device comprising: a fuse area in which a plurality of fuse elements are arranged; first to third ring elements surrounding the fuse area, the first ring element being formed in a first wiring layer, the second ring element being formed in a second wiring layer located above the first wiring layer, the third ring element being formed in a third wiring layer located above the second wiring layer; and first and second connecting ring elements surrounding the fuse area, the first connecting ring element connecting the first and second ring elements, the second connecting ring element connecting the second and third ring elements. The first connecting ring element has a smaller diameter than the second connecting ring element.

In still another embodiment, there is provided a semiconductor device comprising: a fuse area in which a plurality of fuse elements formed in a first wiring layer are arranged; and first to third ring elements surrounding the fuse area, the first ring element being formed in the first wiring layer, the second ring element being formed in a second wiring layer located above the first wiring layer, the third ring element being formed in a third wiring layer located above the second wiring layer. The second ring element has an inner periphery that is positioned at closer to the fuse area than an inner periphery of the third ring element.

### BRIEF DESCRIPTION OF THE DRAWINGS

The above and other features and advantages of the present invention will be more apparent from the following description of certain preferred embodiments taken in conjunction with the accompanying drawings, in which:

FIG. 1 is a plan view representing the layout of a semiconductor memory device;

FIG. 2 is a plan view representing the layout of a fuse area and a surrounding portion thereof according to a first prototype in the course of making the present invention;

FIG. 3 is a cross-sectional view of the fuse area and the surrounding portion thereof of the first prototype;

FIG. 4 is an enlarged view of a portion including part of the fuse area and a guard ring of the first prototype;

FIG. 5 is a plan view representing the layout of fuse area and a surrounding portion thereof according to a first embodiment;

FIG. 6 is a cross-sectional view of the fuse area and the surrounding portion thereof of the first embodiment;

FIG. 7 is an enlarged view of a portion including part of the fuse area and a guard ring of the first embodiment;

FIG. 8 is a cross-sectional view of a fuse area and a surrounding portion thereof according to a second prototype in the course of making the present invention;

FIG. 9 is a cross-sectional view of a fuse area and a surrounding portion thereof according to a second embodiment;

FIG. 10 is a cross-sectional view of a fuse area and a surrounding portion thereof according to a third prototype in the course of making the present invention; and

FIG. 11 is a cross-sectional view of a fuse area and a surrounding portion thereof according to a third embodiment.

### DETAILED DESCRIPTION OF THE EMBODIMENTS

Preferred embodiments of the present invention will be explained below in detail with reference to the accompanying drawings.

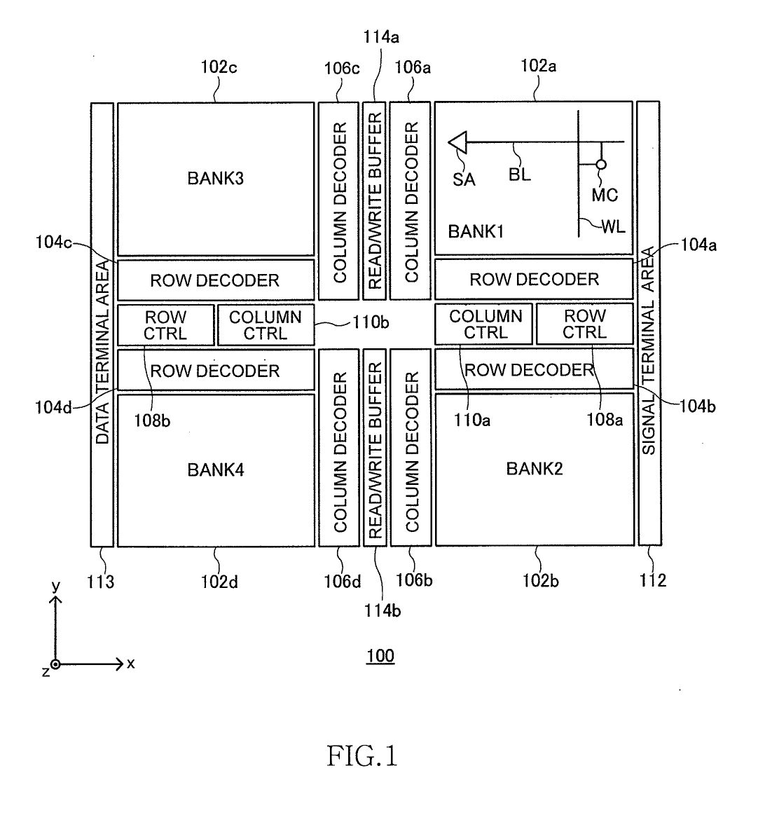

The semiconductor memory device 100 of the embodiments described hereinbelow is a double-data-rate (DDR) type synchronous dynamic random access memory (SDRAM). As depicted in FIG. 1, a rightward direction represents an x-axis direction, an upward direction represents a y-axis direction and a frontward direction represents a z-axis direction.

Referring to FIG. 1, there are provided four memory banks 102a to 102d (collectively referred to as the memory banks 102). Each of these memory banks 102 includes a plurality of word lines WL extending in the y-axis direction, a plurality of bit lines BL extending in the x-axis direction, and memory cells MC located at intersections of the word lines WL and the bit lines BL. A row decoder 104a is disposed along an x-axis side of the memory bank 102a. Similarly, row decoders 104b, 104c and 104d are disposed along x-axis sides of the memory banks 102b, 102c and 102d, respectively. A column decoder 106a is disposed along a y-axis side of the memory bank 102a. Similarly, column decoders 106b, 106c and 106d are disposed along y-axis sides of the memory banks 102b, 102c and 102d, respectively.

A column control circuit 110a and a row control circuit 108a are disposed side by side along the x-axis direction between the row decoders 104a and 104b. The column control circuit 110a and the row control circuit 108a serve to control both of the memory banks 102a and 102b. Similarly, a column control circuit 110b and a row control circuit 108b are disposed side by side along the x-axis direction between the row decoders 104c and 104d. The column control circuit 110b and the row control circuit 108b serve to control both of the memory banks 102c and 102d.

A signal terminal area 112 is disposed along the y-axis side of the memory banks 102a and 102b, and a data terminal area 113 is disposed along the y-axis side of the memory banks 102c and 102d. Address terminals, command terminals and the like are arranged in the signal terminal area 112. Also, data input/output terminals are arranged in the data terminal area 113.

Further, a read/write buffer 114a is provided between the column decoders 106a and 106c, and a read/write buffer 114b is provided between the column decoders 106b and 106d. The read/write buffer 114a is allocated to the memory banks 102a and 102c, whereas the read/write buffer 114b is allocated to the memory banks 102b and 102d.

While the following discussion deals primarily with operation for controlling the memory banks 102a and 102b, essentially the same control operation applies to the memory banks 102c and 102d as well.

Various kinds of signals, such as address signals and command signals, are input into the signal terminal area 112. These signals are processed by a main controller (not shown) provided in the vicinity of the signal terminal area 112 and then transferred to the row control circuit 108a and the column control circuit 110a. Among the address signals, those indicating row addresses are supplied to the row control circuits 108a, 108b and the row decoders 104a to 104d and those indicating column addresses are supplied to the column control circuits 110a, 110b and the column decoders 106a to 106d. The address signals also contain information specifying which one of the memory banks 102a to 102d is to be accessed.

The row decoder 104a is controlled by the row control circuit 108a to select one of the word lines WL of the memory bank 102a in accordance with a specified row address. The row decoder 104b is controlled by the row control circuit 108a to select one of the word lines WL of the memory bank 102b in accordance with a specified row address.

The column decoder 106a is controlled by the column control circuit 110a to select one of the bit lines BL of the memory bank 102a in accordance with a specified column address. The selected bit line BL is connected to the read/write buffer 114a via a sense amplifier SA. Consequently, data in the memory cell MC to be accessed becomes accessible via the data input/output terminal provided in the data terminal area 113. Similarly, the column decoder 106b is controlled by the column control circuit 110a to select one of the bit lines BL in the memory bank 102b in accordance with a specified column address. The selected bit line BL is connected to the read/write buffer 114b via the sense amplifier SA. Then, a data signal obtained as a result of amplification by the read/write buffer 114b becomes accessible from the data terminal area 113.

There are provided fuse areas for registering relief addresses in the row control circuits 108a, 108b and the column control circuits 110a, 110b. When an input row address coincides with one of the registered relief addresses (i.e., the address of a defective cell), the row control circuit 108a transmits a relevant relief address signal to one of the row decoders 104a, 104b. Upon receiving the relief address signal, the row decoder 104a or 104b, replaces access to the defective cell with access to a predefined redundant cell. The row control circuit 108b and the column control circuits 110a, 110b operate in essentially the same way as the row control circuit 108a.

The following discussion focuses mainly on the configuration of the fuse area and a surrounding portion thereof provided in the row control circuit 108, for example. The discussion includes an explanation of a prototype followed by an explanation of a configuration according to a first embodiment of the present invention.

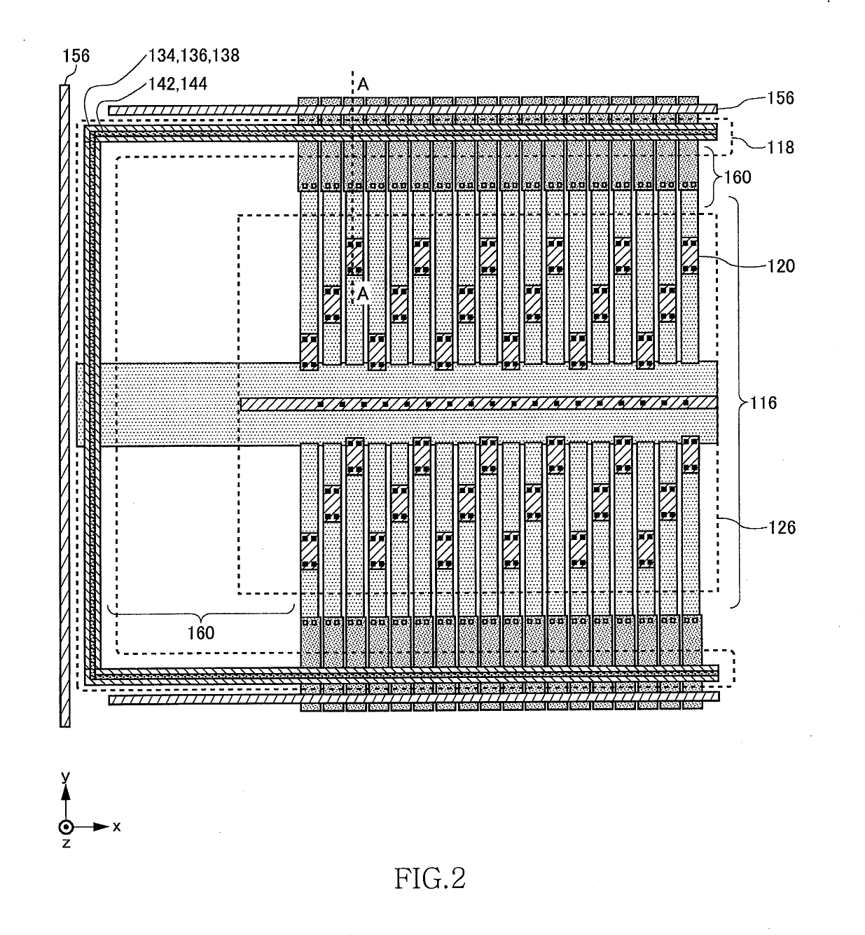

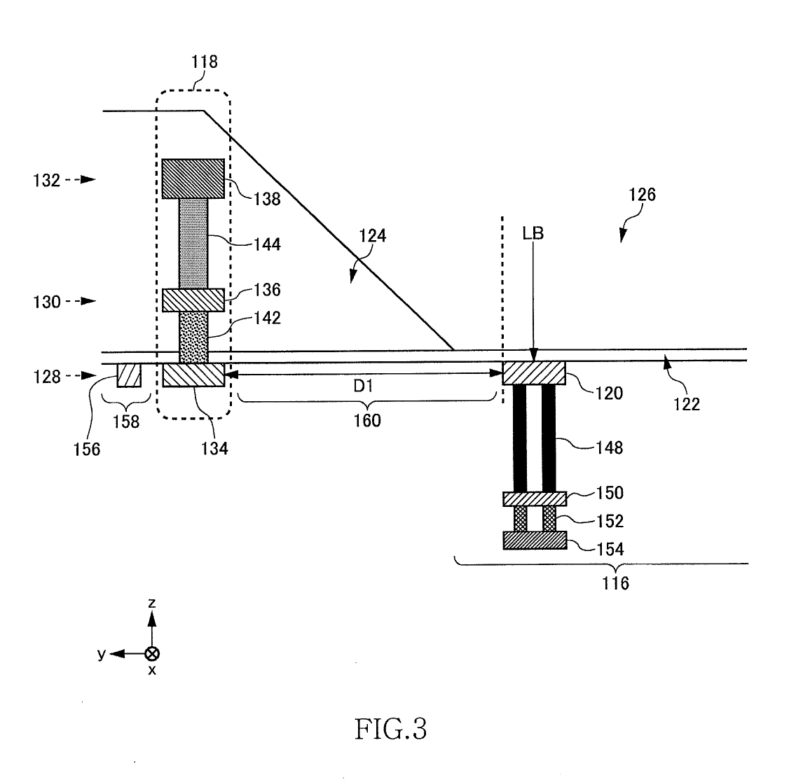

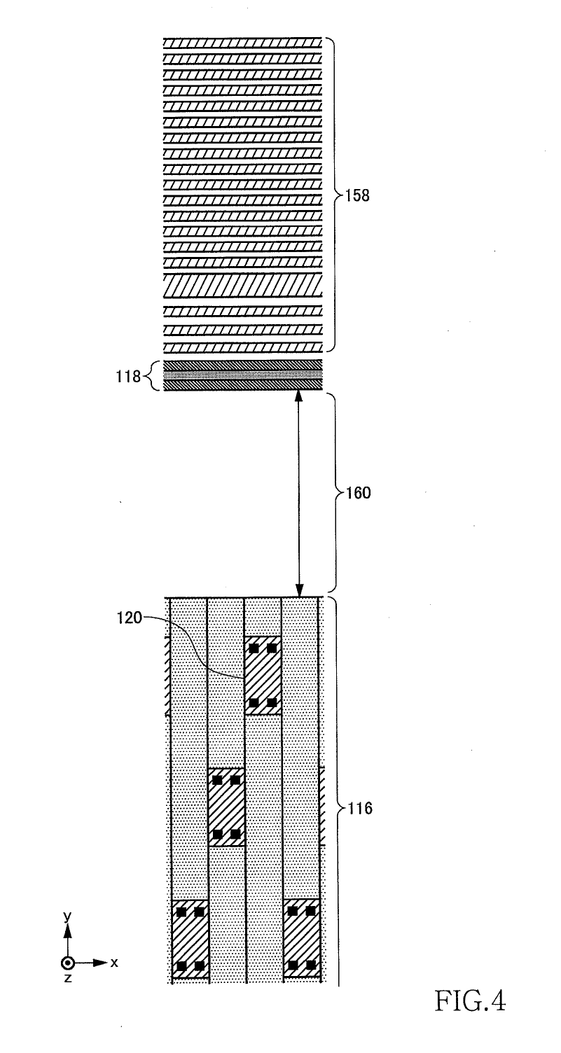

FIG. 2 is a plan view representing the layout of a fuse area 116 and a surrounding portion thereof of a semiconductor memory device 100 according to the first prototype in the course of making the present invention, and FIG. 3 is a cross-sectional view of the fuse area 116 and the surrounding portion thereof of the first prototype representing a cross section of the semiconductor memory device 100 taken along line A-A of FIG. 2. Also, FIG. 4 is an enlarged view of a portion including part of the fuse area 116 and a guard ring 118. The first prototype is now described in detail with reference to FIGS. 2, 3 and 4.

As depicted in FIG. 2, the fuse area 116 includes a plurality of fuse elements 120 which are arranged in an xy-plane direction and can be blown by irradiation with a laser beam. Spacings between any two adjacent fuse elements 120 are determined depending on the precision of the laser beam.

Referring to FIG. 3, the fuse elements 120 are covered with a silicon dioxide film 122 formed immediately above and the silicon dioxide film 122 is further covered with a passivation film 124 (protective film) formed above. The passivation film 124 is so fashioned that an opening 126 is formed directly above the fuse elements 120. The opening 126 in the passivation film 124 is made to ensure that energy of the laser beam LB is not attenuated by the passivation film 124 during irradiation of the fuse elements 120 with the laser beam LB. The passivation film 124 is formed by depositing the same on the silicon dioxide film 122 and, therefore, a side surface of the opening 126 is inclined with respect to the z-axis direction as illustrated in FIG. 3. In other words, the opening 126 is larger at an upper side than at a lower side (i.e., the side of the fuse element 120). As seen in FIG. 2, the opening 126 has a rectangular shape in the xy-plane.

As depicted in FIG. 3, the guard ring 118 is embedded in the passivation film 124. The guard ring 118 is formed to surround the opening 126 (FIGS. 2 and 3). Referring to FIG. 3, the guard ring 118 includes constituent elements formed in three layers, that is, a first layer 128, a second layer 130 and a third layer 132, which may be wiring layers. Formed in the first layer 128, the second layer 130 and the third layer 132 are a first ring element 134, a second ring element 136 and a third ring element 138, respectively. These ring elements 134, 136, 138 need not necessarily be wirings used for signal transmission.

The first ring element 134 and the second ring element 136 are interconnected by a first connecting ring element 142 while the second ring element 136 and the third ring element 138 are interconnected by a second connecting ring element 144. This means that the guard ring 118 depicted in FIG. 3 is a single-structured ring member including the first to third ring elements 134, 136, 138 and the first and second connecting ring elements 142, 144 interconnecting the ring elements 134, 136, 138. The fuse area 116 is surrounded by the guard ring 118 having the above-described three-layer structure and the individual ring elements 134, 136, 138 of this three-layer structure are connected in a straight line along the z-axis direction (FIG. 3).

The individual fuse elements 120 are formed in the first layer 128 that is the same layer in which the first ring element 134 is formed. The fuse elements 120 are connected to a cell wiring layer 150 by vias 148 and the cell wiring layer 150 is connected to a diffusion layer 154 formed further below by vias 152. The cell wiring layer 150 is connected to a relief circuit (not shown) and the like located outside the guard ring 118 (i.e., in a positive direction of the y-axis as depicted in FIG. 3) by unillustrated signal lines.

When the laser beam LB is emitted to irradiate the fuse elements 120 through the opening 126, the laser beam LB passes through the silicon dioxide film 122 and melts the fuse element 120. The guard ring 118 surrounding the opening 126 protects various kinds of electronic circuits including the relief circuit outside the guard ring 118 from breakdown and stress potentially caused by laser beam irradiation. The guard ring 118 also protects the electronic circuits and wirings provided outside the guard ring 118 from such foreign matter as water or dust which may intrude through the opening 126. This means that the guard ring 118 functions as a protective wall for an electronic circuit area.

In the structure depicted in FIGS. 2, 3 and 4, the distance between a bottom of the guard ring 118, or the first ring element 134, and the fuse element 120 is expressed by the symbol D1. In the first layer 128, there is provided a first wiring area 158 for arranging various kinds of wirings (first wirings 156) outside the first ring element 134. As an area inside of the guard ring 118 (i.e., in a negative direction of the y-axis as depicted in FIG. 3, or the side of the opening 126) is not protected by the guard ring 118, it is not possible to arrange the first wirings 156 in this area. Thus, the area inside of the guard ring 118 is hereinafter referred to as a non-wiring area 160. The inventors considered that the non-wiring area 160 would be too large and could not be effectively used as a space for arranging circuitry since the distance D1 is too large in the aforementioned structure of FIGS. 2, 3 and 4.

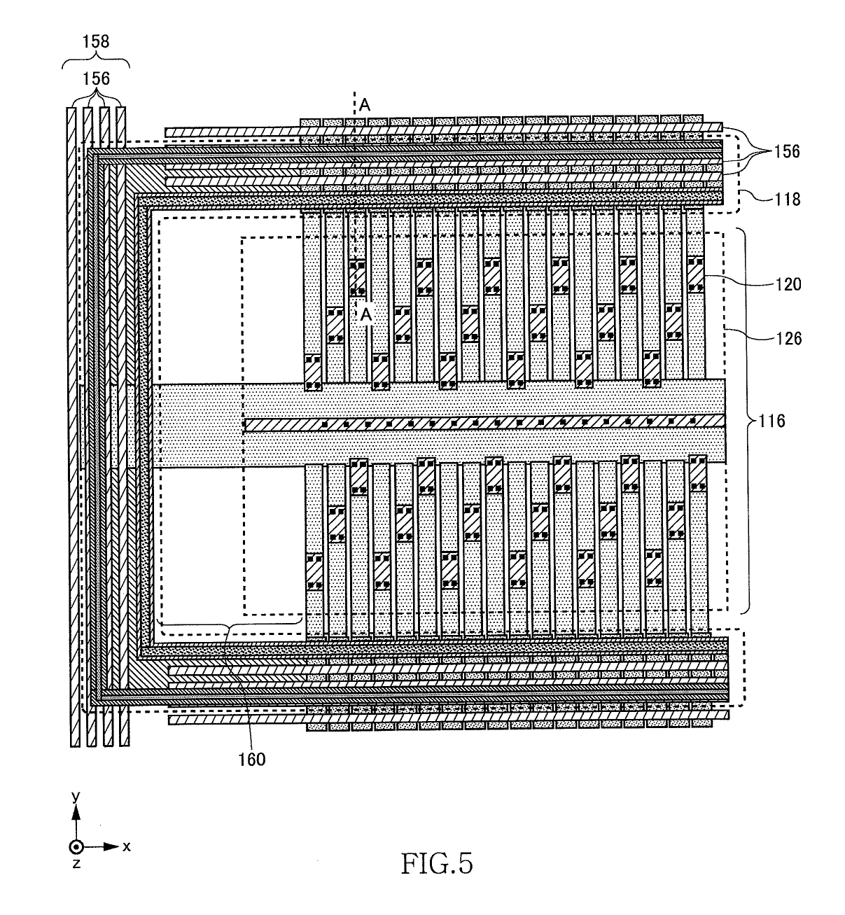

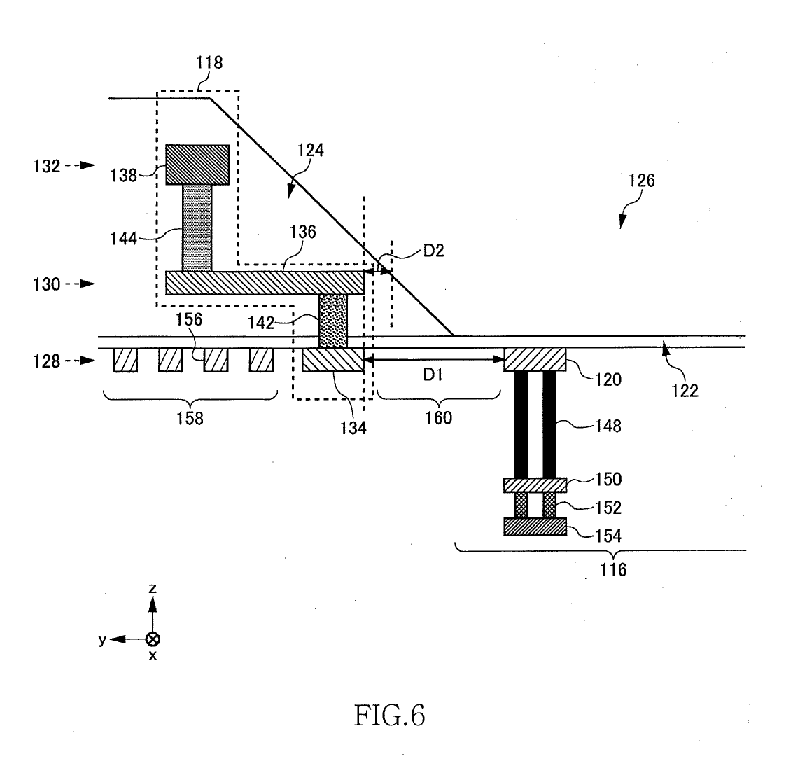

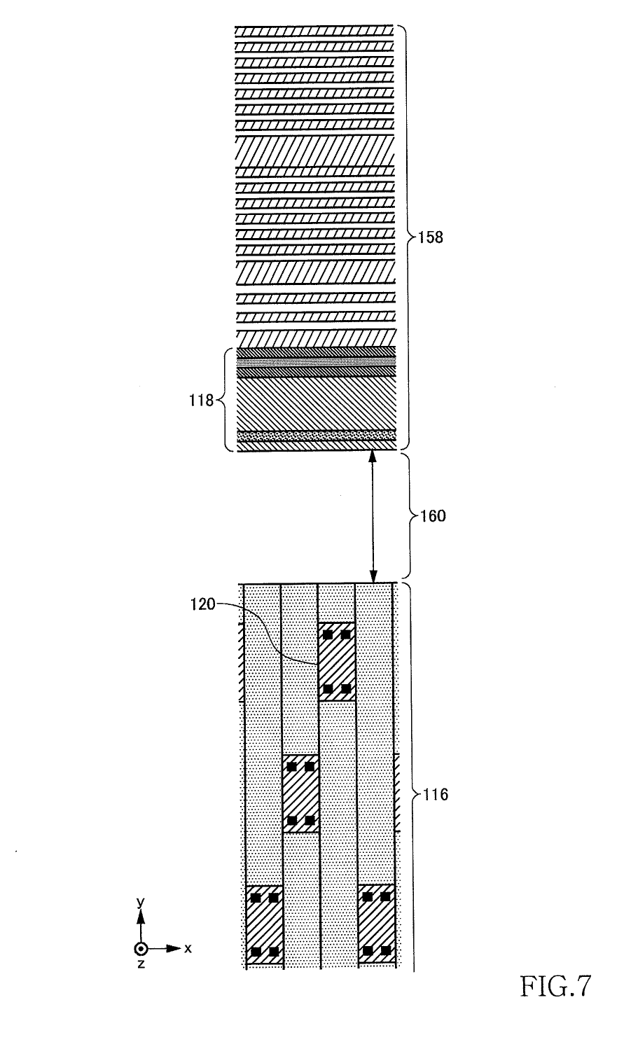

FIG. 5 is a plan view representing the layout of a fuse area 116 and a surrounding portion thereof of a semiconductor memory device 100 according to the first embodiment, and FIG. 6 is a cross-sectional view of the fuse area 116 and the surrounding portion thereof of the first embodiment representing a cross section of the semiconductor memory device 100 taken along line A-A of FIG. 5. Also, FIG. 7 is an enlarged view of a portion including part of the fuse area 116 and a guard ring 118. The first embodiment is now described in detail with reference to FIGS. 5, 6 and 7.

As illustrated in FIG. 6, a second ring element 136 extends inward (i.e., in a negative direction of the y-axis, or toward an opening 126) and a first ring element 134 is connected to an inward part of the second ring element 136 in the first embodiment. Therefore, a first connecting ring element 142 and a second connecting ring element 144 are not joined in line along the z-axis direction. This means that the first ring element 134, the second ring element 136, a third ring element 138, the first connecting ring element 142 and the second connecting ring element 144 are not connected in a straight line along the z-axis direction. As the fuse area 116 and the surrounding portion thereof of this embodiment are structured such that the second ring element 136 extends inward, the first ring element 134 is located closer to the opening 126 and, thus, distance D1 is made smaller.

This structure of the first embodiment in which the first ring element 134 is located below the inward part of the second ring element 136 has a narrower non-wiring area 160, thereby providing a broader first wiring area 158. As a space beneath the second ring element 136 provides an area unoccupied by the first ring element 134, it is possible to use this area as the first wiring area 158. Using the first wiring area 158 thus broadened, it is possible to lay more wirings without any increase in the scale of circuitry. The increase in the first wiring area 158 may serve also to increase the thicknesses of first wirings 156, resulting in a reduction in resistances of the wirings. Alternatively, an additional power supply bus line may be provided. Allowing such measures to be taken, the semiconductor memory device 100 of the first embodiment makes it easier to increase signal transmission speed. Also, the semiconductor memory device 100 makes it possible to make the first wiring area 158 larger than in the first prototype not only in the y-axis direction but also in the x-axis direction.

A discussion given below includes an explanation of another prototype in which the guard ring 118 has a four-layer structure followed by an explanation of a configuration according to a second embodiment in which the present invention is applied to the four-layered guard ring 118.

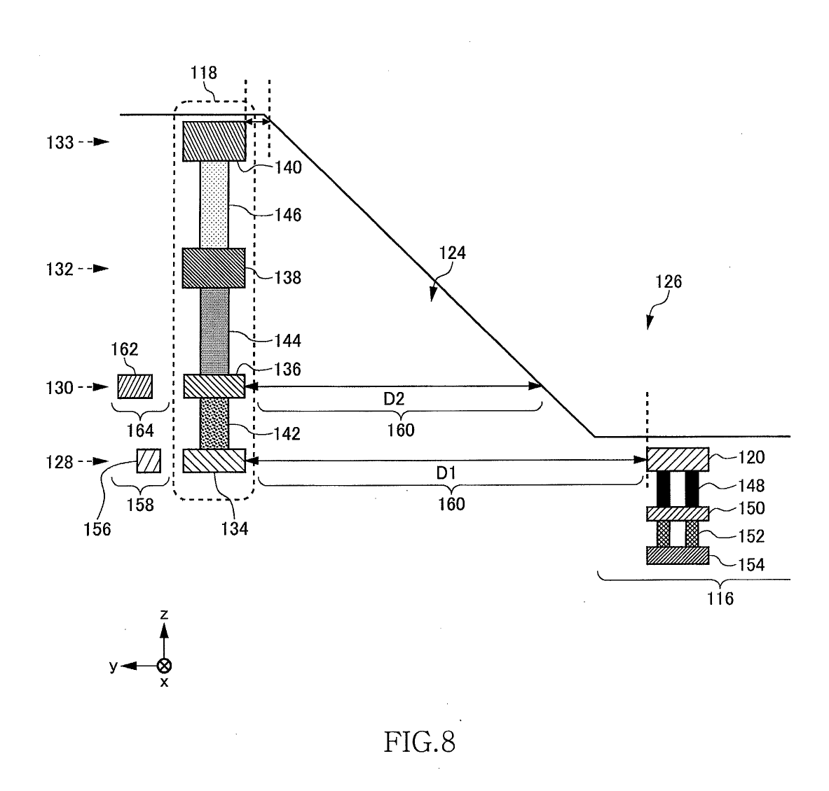

FIG. 8 is a cross-sectional view of a fuse area 116 and a surrounding portion thereof of a semiconductor memory device 100 according to the second prototype in the course of making the present invention. A guard ring 118 depicted in FIG. 8 includes elements disposed in four layers, that is, a first layer 128, a second layer 130, a third layer 132 and a fourth layer 133. Formed in the first layer 128, the second layer 130, the third layer 132 and the fourth layer 133 are a first ring element 134, a second ring element 136, a third ring element 138 and a fourth ring element 140, respectively. In the case a passivation film 124 has a sufficient thickness, the guard ring 118 may be structured in more than four layers.

The first ring element 134 and the second ring element 136 are interconnected by a first connecting ring element 142 while the second ring element 136 and the third ring element 138 are interconnected by a second connecting ring element 144. Likewise, the third ring element 138 and the fourth ring element 140 are interconnected by a third connecting ring element 146. The guard ring 118 depicted in FIG. 8 is a single-structured ring member including the first to fourth ring elements 134, 136, 138, 140 and the first to third connecting ring elements 142, 144, 146 interconnecting the ring elements 134, 136, 138, 140. As is the case with the first prototype, the individual ring elements 134, 136, 138, 140 of the four-layer structure depicted in FIG. 8 are connected in a straight line along the z-axis direction.

In the structure depicted in FIG. 8, second wirings 162 are arranged in a second wiring area 164 formed in the second layer 130. The distance between the second ring element 136 and an opening 126 is expressed by the symbol D2. Since an area inside of the guard ring 118 (i.e., in the negative direction of the y-axis as depicted in FIG. 8) is not protected by the guard ring 118, it is not possible to arrange first wirings 156 or second wirings 162 in this area. Consequently, as is the case with the structure of the first prototype, a large non-wiring area 160 is likely to be formed in either of the first layer 128 and the second layer 130.

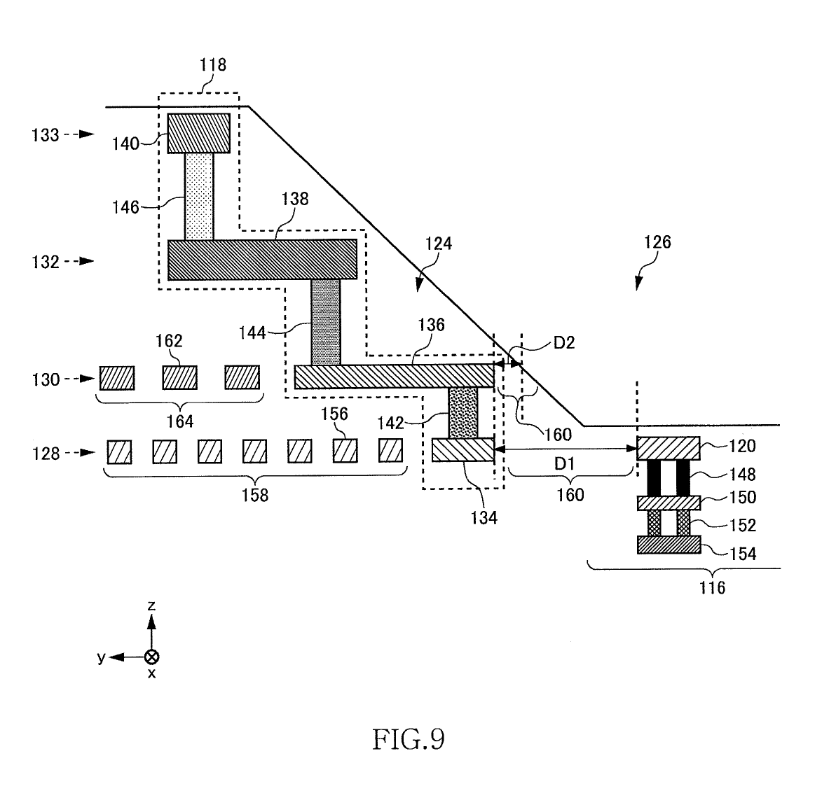

FIG. 9 is a cross-sectional view of a fuse area 116 and a surrounding portion thereof of a semiconductor memory device 100 according to the second embodiment. As illustrated in FIG. 9, a second ring element 136 and a third ring element 138 extend toward an opening 126 in this embodiment. A first ring element 134 is connected to an inward part of the second ring element 136 and the second ring element 136 is connected to an inward part of the third ring element 138. Therefore, a first connecting ring element 142, a second connecting ring element 144 and a third connecting ring element 146 are not joined in line along the z-axis direction. This means that the first ring element 134, the second ring element 136, the third ring element 138, a fourth ring element 140, the first connecting ring element 142, the second connecting ring element 144 and the third connecting ring element 146 are not connected in a straight line along the z-axis direction. As the fuse area 116 and the surrounding portion thereof of this embodiment are structured such that the third ring element 138 and the second ring element 136 extend inward, distances D1 and D2 are made smaller.

This structure of the second embodiment in which the first ring element 134 is located below the inward part of the second ring element 136 and the second ring element 136 is located below the inward part of the third ring element 138 has narrower non-wiring areas 160, thereby providing a broader first wiring area 158 and a broader second wiring area 164. This is because the first wiring area 158 (an area unoccupied by the first ring element 134) is held beneath the second ring element 136 and the second wiring area 164 (an area unoccupied by the second ring element 136) is held beneath the third ring element 138. The first wiring area 158 and the second wiring area 164 thus broadened provide space savings, making it possible to lay more wirings. The increase in the first wiring area 158 and the second wiring area 164 may serve to increase the thicknesses of first wirings 156 and second wirings 162, resulting in a reduction in resistances of the wirings. Alternatively, additional power supply bus lines may be provided. Allowing such measures to be taken, the semiconductor memory device 100 of the second embodiment makes it easier to increase signal transmission speed. Also, the semiconductor memory device 100 makes it possible to make the first wiring area 158 and the second wiring area 164 larger than in the second prototype not only in the y-axis direction but also in the x-axis direction.

Finally, a discussion given below includes an explanation of still another prototype in which the guard ring 118 has a two-layer structure followed by an explanation of a configuration according to a third embodiment in which the present invention is applied to the two-layered guard ring 118.

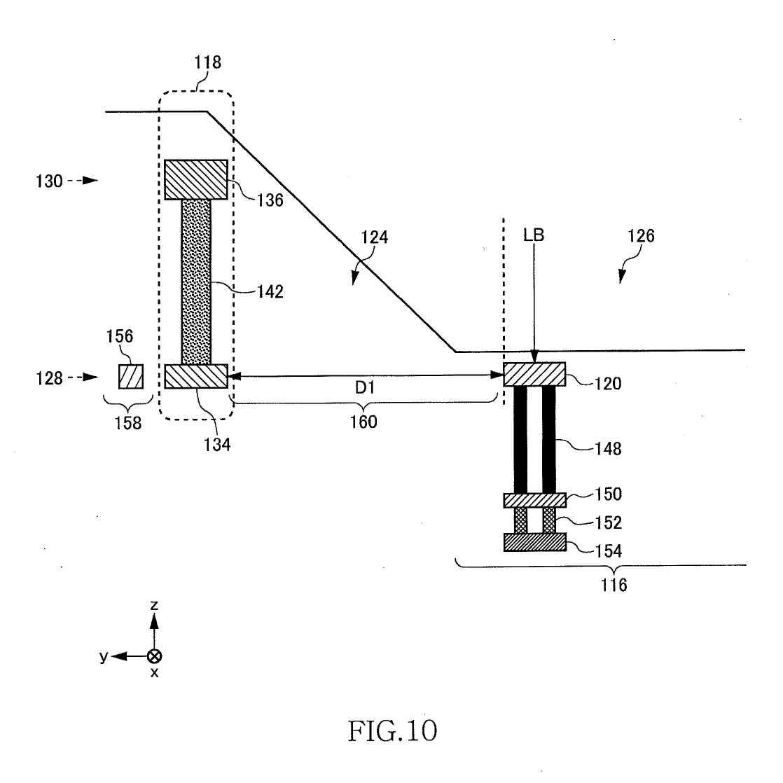

FIG. 10 is a cross-sectional view of a fuse area 116 and a surrounding portion thereof of a semiconductor memory device 100 according to the third prototype in the course of making the present invention. A guard ring 118 depicted in FIG. 10 includes elements disposed in two layers, that is, a first layer 128 and a second layer 130. Formed in the first layer 128 and the second layer 130 are a first ring element 134 and a second ring element 136, respectively.

The first ring element 134 and the second ring element 136 are interconnected by a first connecting ring element 142. The guard ring 118 depicted in FIG. 10 is a single-structured ring member including the first and second ring elements 134, 136 and the first connecting ring element 142 interconnecting the ring elements 134, 136. As is the case with the first and second prototypes, the individual ring elements 134, 136 of the two-layer structure depicted in FIG. 10 are connected in a straight line along the z-axis direction. Thus, as is the case with the structures of the first and second prototypes, a large non-wiring area 160 is likely to be formed in the first layer 128.

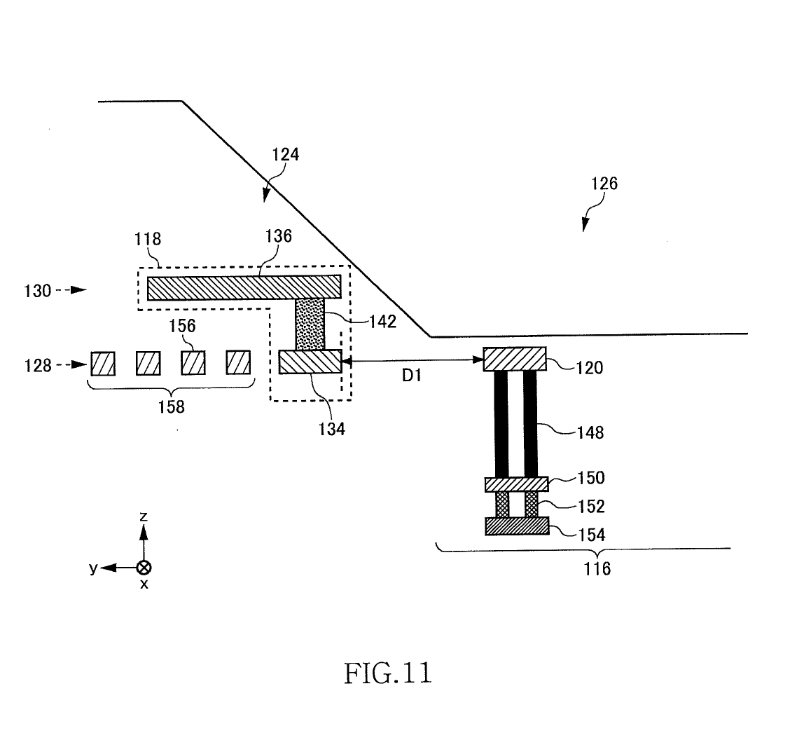

FIG. 11 is a cross-sectional view of a fuse area 116 and a surrounding portion thereof of a semiconductor memory device 100 according to the third embodiment. As illustrated in FIG. 11, a second ring element 136 extends toward an opening 126 in this embodiment. A first ring element 134 is connected to an inward part of the second ring element 136. As the fuse area 116 and the surrounding portion thereof of this embodiment are structured such that the second ring element 136 extends inward as compared to the above-described structure of the third prototype, distance D1 is made smaller.

This structure of the third embodiment in which the first ring element 134 is located below the inward part of the second ring element 136 has a narrower non-wiring area 160, thereby providing a broader first wiring area 158. The first wiring area 158 thus broadened provides space savings, making it possible to lay more wirings. The semiconductor memory device 100 of the third embodiment makes it possible to make the first wiring area 158 larger than in the third prototype not only in the y-axis direction but also in the x-axis direction.

The semiconductor memory device 100 has thus far been described, by way of examples, with reference to the preferred embodiments. In a case where the passivation film 124 formed by depositing the same on the silicon dioxide film 122, the side surface of the opening 126 is likely to become inclined as depicted in the cross-sectional view of FIG. 3 and the like, for instance. If the first ring element 134 or the like is located closer to the opening 126 as discussed in the foregoing preferred embodiments in consideration of the aforementioned structure of the opening 126, it is possible to make the first wiring area 158 and the second wiring area 164 extend closer toward the opening 126. Since the above-described structures of the invention provide space savings, making it easier to lay a large number of wirings such as first wiring 156 and second wiring 162, it is possible to achieve higher density packaging of the fuse elements 120. Alternatively, the structures of the invention make it possible to increase the thicknesses of first wirings 156 or the like or provide an additional power supply bus line, contributing thereby to prevent a reduction in signal transmission speed.

While the present invention has thus far been described with reference to the preferred embodiments thereof, these embodiments are simply illustrative. It will be evident to those skilled in the art that the above-described arrangements of the embodiments may be modified or altered in various ways without departing from the scope and spirit of the present invention defined by the appended claims and that such modifications and alterations fall within the scope of the invention. It should therefore be recognized that the foregoing description of the Specification and the accompanying drawings do not restrict the present invention but are illustrative of the invention.

The present invention is not limited to semiconductor memory devices. The present invention can be applied widely to any types of semiconductor devices.

What is claimed is:

1. A semiconductor device comprising:
a fuse area in which a plurality of fuse elements are arranged; and
a guard ring surrounding the fuse area, the guard ring including a first ring element formed in a first wiring layer and a second ring element formed in a second wiring layer located above the first wiring layer,
wherein the first ring element has an outer periphery that is positioned at closer to the fuse area than an outer periphery of the second ring element.

2. The semiconductor device as claimed in claim 1, further comprising a first wiring formed in the first wiring layer, the first wiring being covered with the second ring element.

3. The semiconductor device as claimed in claim 2, wherein the first wiring transmits a signal indicating a connecting state of at least one of the fuse elements.

4. The semiconductor device as claimed in claim 1 further comprising a protective film covering both the first wiring layer and the second wiring layer, wherein
the protective film has an opening formed above the fuse area, and
the guard ring is formed surrounding the opening of the protective film.

5. The semiconductor device as claimed in claim 4, wherein the opening has larger diameter at an upper side than at a lower side.

6. The semiconductor device as claimed in claim 1, wherein the guard ring further includes a third ring element formed in a third wiring layer which is located above the second layer.

7. The semiconductor device as claimed in claim 6, wherein the outer periphery of the second guard ring is positioned at closer to the fuse area than an outer periphery of the third ring element.

8. The semiconductor device as claimed in claim 7, further comprising a second wiring formed in the second wiring layer, the second wiring being covered with the third ring element.

9. The semiconductor device as claimed in claim 1, wherein the fuse elements is formed in the first wiring layer.

10. A semiconductor device comprising:
a fuse area in which a plurality of fuse elements are arranged;
first to third ring elements surrounding the fuse area, the first ring element being formed in a first wiring layer, the second ring element being formed in a second wiring layer located above the first wiring layer, the third ring element being formed in a third wiring layer located above the second wiring layer; and
first and second connecting ring elements surrounding the fuse area, the first connecting ring element connecting the first and second ring elements, the second connecting ring element connecting the second and third ring elements,
wherein the first connecting ring element has a smaller diameter than the second connecting ring element.

11. The semiconductor device as claimed in claim 10, further comprising a first wiring formed in the first wiring layer, the first wiring being covered with the second ring element.

12. The semiconductor device as claimed in claim further comprising a protective film covering the first to third ring elements and the first and second connecting ring elements,
wherein the fuse elements are not covered with the protective film.

13. The semiconductor device as claimed in claim 10, further comprising:
a fourth ring element surrounding the fuse area, the fourth ring element being formed in a fourth wiring layer located above the third wiring layer; and
a third connecting ring element surrounding the fuse area, the third connecting ring element connecting the third and fourth ring elements,
wherein the second connecting ring element has a smaller diameter than the third connecting ring element.

14. The semiconductor device as claimed in claim 13, further comprising a second wiring formed in the second wiring layer, the second wiring being covered with the third ring element.

15. The semiconductor device as claimed in claim 14, further comprising a third wiring formed in the first wiring layer, the third wiring being covered with the third ring element without covered with the second ring element.

16. The semiconductor device as claimed in claim 10, wherein the fuse elements is formed in the first wiring layer.

17. A semiconductor device comprising:
a fuse area in which a plurality of fuse elements formed in a first wiring layer are arranged; and
first to third ring elements surrounding the fuse area, the first ring element being formed in the first wiring layer, the second ring element being formed in a second wiring layer located above the first wiring layer, the third ring element being formed in a third wiring layer located above the second wiring layer,
wherein the second ring element has an inner periphery that is positioned at closer to the fuse area than an inner periphery of the third ring element.

18. The semiconductor device as claimed in claim 17, further comprising a first wiring formed in the first wiring layer, the first wiring being covered with the second ring element.

19. The semiconductor device as claimed in claim 17, further comprising a fourth ring element surrounding the fuse area, the fourth ring element being formed in a fourth wiring layer located above the third wiring layer,
wherein the inner periphery of the third ring element is positioned at closer to the fuse area than an inner periphery of the fourth ring element.

20. The semiconductor device as claimed in claim 19, further comprising a second wiring formed in the second wiring layer, the second wiring being covered with the third ring element.
